(19) United States
(12) Patent Application Publication
(10) Pub. No.: US 2026/0066230 A1
(43) Pub. Date: Mar. 5, 2026

(54) POWER COMBINER FOR COUPLING RF SIGNALS FOR A PLASMA PROCESS SUPPLY SYSTEM AND A PLASMA PROCESS SYSTEM

(71) Applicant: TRUMPF Hüttinger GmbH + Co. KG, Freiburg (DE)

(72) Inventors: Florian Maier, Pfaffenweiler (DE); Roland Lodholz, Ebringen (DE); Christian Wangler, March (DE); Modashree Rangesh, Ashland, MA (US)

(21) Appl. No.: 19/379,787

(22) Filed: Nov. 5, 2025

Related U.S. Application Data
(63) Continuation of application No. PCT/EP2024/062329, filed on May 3, 2024.

(30) Foreign Application Priority Data
May 5, 2023 (DE) 10 2023 111 812.9

(51) Int. Cl. H01J 37/32; H03F 1/30; H03F 3/24; H03F 3/60

(52) U.S. Cl. CPC H01J 37/32183; H03F 1/30; H03F 3/245; H03F 3/602

(57) ABSTRACT

A power combiner for coupling RF signals, in particular designed for a plasma process supply system and a plasma process system, the power combiner being designed for a predefined operating frequency range with a frequency in the range of 2 MHz to 200 MHz, in particular in the range of 10 MHz to 50 MHz, designed for an output power ≥2 kW, preferably ≥4 kW, the power combiner including multiple inputs designed for connecting RF power amplifier stages, a main output, and multiple coupling elements, in particular designed as inductors, wherein each coupling element connects one input to the main output. The power combiner further includes a balancing circuit which connects the inputs to one another, having an energy absorber, in particular designed as a resistor, and a balancing line with a fixed characteristic impedance and a length of n*λ/2, where n∈ [symbol] .

### CROSS REFERENCE TO RELATED APPLICATIONS

This application is a continuation of International Application No. PCT/EP2024/062329 (published as WO 2024/231303 A1), filed on May 3, 2024, and claims benefit to German Patent Application No. DE 10 2023 111 812.9, filed on May 5, 2023. The aforementioned applications are hereby incorporated by reference herein.

### FIELD

The present invention relates to a power combiner for coupling RF signals, an RF power amplifier unit having such a power combiner as well as a plasma process supply system and a plasma process system, and a method for supplying a load.

### BACKGROUND

A plasma process supply system is designed for supplying a plasma process arrangement. A plasma process arrangement refers to an arrangement in which a plasma is generated and maintained in order to start and keep a process going. This can be a gas laser excitation. In particular, it can be a plasma processing arrangement. With such a plasma processing arrangement, materials and in particular their surfaces can be processed, for example coated, etched or activated. Such plasma process arrangements can be found, for example, in the production of architectural glass, photovoltaic modules, displays, semiconductor components such as microcontrollers or semiconductor memory chips, etc. As these are high-precision processes, the demands placed on such plasma process arrangements and consequently also on the plasma process supply systems supplying them with electric power in terms of measurement and control accuracy, reliability, continuous operation, efficiency, etc. are extraordinarily high. Such a plasma process supply system is often designed for powers ≥2 kW, preferably ≥4 kW and frequencies in the range of 2 MHz to 200 MHz, in particular in the range of 10 MHz to 50 MHz. Such a plasma process supply system often has one or more radio frequency signal sources designed to collectively supply this required power and control it according to the specifications of the process. In addition, a plasma process supply system often has one or more impedance matching circuits designed to adapt the impedance at the output of the radio frequency signal source(s) to the impedance at the input of the plasma process.

The output power of radio frequency signal sources, in particular RF power amplifier stages with transistor amplifiers, is limited to a few 100 W to a few kW by the transistors currently available. In order to achieve a higher output power, multiple radio frequency signal sources must therefore be interconnected using a power combiner. The power combiners should have the lowest possible losses with a large bandwidth. Radio frequency signal sources for plasma process supply systems in particular require such power combiners. As the demands on the measurement and control accuracy and stability of plasma process supply systems are constantly increasing, the corresponding demands on the power combiners used are also constantly growing.

At the same time, the inputs of the power combiner to which the radio frequency signal sources can be connected should be decoupled from one another as well as possible in order to avoid cross-feeding of the radio frequency signal sources and an uneven distribution of reflected output power. If the amplitudes, phases or internal impedances of the radio frequency signal sources connected to the power combiner are unequal, a push-pull signal harmful to the radio frequency signal sources is generated. In addition or alternatively, the phases and/or amplitude as well as the load impedance of the individual amplifiers can change if the reflected power is unevenly distributed. This can lead to excessive stress on the amplifier under the heaviest load.

For this reason, the inputs of power combiners are usually connected via so-called balancing circuits. Such balancing circuits can, for example, have a resistor and/or a capacitor. The inputs are often connected to one another via the balancing circuit, in particular via a common star point.

A power combiner for such processes is known, for example, from DE 20 2016 008 958 U1.

The disadvantage of such a power combiner is that it is only suitable for a limited power output. This is because the number of radio frequency signal sources that can be arranged around it is limited by the space available.

### SUMMARY

In an embodiment, the present disclosure provides a power combiner for coupling RF signals, in particular designed for a plasma process supply system and a plasma process system, the power combiner being designed for a predefined operating frequency range with a frequency in the range of 2 MHz to 200 MHz, in particular in the range of 10 MHz to 50 MHz, designed for an output power ≥2 kW, preferably ≥4 kW, the power combiner comprising multiple inputs designed for connecting RF power amplifier stages, a main output, and multiple coupling elements, in particular designed as inductors, wherein each coupling element connects one input to the main output. The power combiner further comprises a balancing circuit which connects the inputs to one another, having an energy absorber, in particular designed as a resistor, and a balancing line with a fixed characteristic impedance and a length of n*λ/2, where n∈ [symbol] .

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1a, and FIG. 1b illustrate embodiments of a power amplifier unit with two cooling units each;

FIG. 2 illustrates an embodiment of a power amplifier unit with three cooling units;

FIG. 3 illustrates an embodiment of a power amplifier unit with four cooling units;

FIG. 4a, and FIG. 4b illustrate embodiments of a power amplifier unit with two cooling units each;

FIG. 5 illustrates a schematic view of a power amplifier unit; and

FIG. 6 illustrates a plasma process system with a plasma process supply system.

### DETAILED DESCRIPTION

In an embodiment, the present disclosure provides a power combiner that is suitable for higher outputs.

In accordance with the present disclosure, a power combiner designed for a predefined operating frequency range for coupling RF signals with a frequency in the range of 2 MHz to 200 MHz, in particular in the range of 10 MHz to 50 MHz, designed for an output power ≥2 kW, preferably ≥4 kW, is provided accordingly, having:
a) multiple inputs designed for connecting RF power amplifier stages,
b) a main output,
c) multiple coupling elements, in particular designed as inductors, wherein each coupling element connects one input to the main output,
d) a balancing circuit which connects the inputs to one another, having:
i) an energy absorber, in particular designed as a resistor, and
ii) a balancing line with a fixed characteristic impedance and a length of n*λ/2, where n∈ [symbol] .

An “operating frequency range” refers to a frequency range within which the power combiner and the RF power amplifier stages that can be connected to it are operated, i.e., what they are designed for. This can be a very narrow-band operating frequency range, such as 13.54 MHz to 13.58 MHz, or a slightly wider band, such as 13.06 MHz to 14.06 MHz. In both cases, the center frequency would be 13.56 MHz. An operating frequency range is usually specified by the manufacturer of a power combiner as the nominal frequency range. This will be specified differently depending on the area of application of the power combiner. If a power combiner is part of an RF power amplifier unit, it is also designed for at least this operating frequency range.

Here, λ generally refers to the wavelength of the radio frequency signals within the corresponding line, i.e., here within the balancing line, at a frequency within the operating frequency range, in particular the center frequency of the operating frequency range.

n∈ [symbol] means that n can be a natural number, i.e., n=1, 2, 3, 4, . . .

An energy absorber can be a component that is suitable for extracting electric energy from the power combiner and converting it into heat, for example, like a resistor. However, it is also provided that this component is designed to convert the energy at least partially in order to make this part available again at another point.

A coupling element can be, for example, an inductor or a coupling line with a predetermined length, such as λ/4. If the multiple coupling elements are all inductors, for example, they can advantageously always have the same inductance value, in particular be identical in construction. The multiple RF power amplifier stages often cannot be arranged very close together because they
often generate so much heat that they have to be cooled by cooling units, and/or
carry such high currents and voltages due to their high power generation that they would negatively influence one another by radiating high-frequency fields.

One solution is to arrange the RF power amplifier stages further apart from one another and/or to shield them appropriately. In both cases, the outputs of the RF power amplifier stages can then only be arranged at a distance from one another. They therefore have an unfavorable distance for the power combiner.

If the inputs of a power combiner are far apart, the balancing line of the balancing circuit to the star point can become long and deviate from the theoretically ideal 0 mm. Such a long balancing line between the balancing circuit and the star point can result in unwanted couplings with phase distortion. This would worsen the coupling and input matching. Attempts to compensate for these couplings using balancing circuits or attenuators have so far been unsuccessful and/or have led to undesirable power losses, which, in addition to the loss of efficiency at these power outputs, often lead to an undesirably high heat development.

In such arrangements, however, the balancing line with the described design and in particular with the described length can lead to great advantages.

The coupling elements can be arranged in such a way that they have little or no influence on one another. The term “little influence” here refers to an influence that is so small that it is not significant according to the laws of physics.

In particular, the fixed characteristic impedance of the balancing line can be equal to the characteristic impedance at the corresponding input.

In particular, the fixed characteristic impedance of the balancing line can be equal to an integer multiple of the characteristic impedance at the corresponding input.

In particular, the fixed characteristic impedance of the balancing line can be equal to an integer divisor of the characteristic impedance at the corresponding input.

In particular, the fixed characteristic impedance of the balancing line can be equal to 25 Ω, 50 Ω or 100 Ω.

By using such a balancing line with a length of n*λ/2, in the balancing circuit of the power combiner, a deterioration of the coupling and input matching of the power combiner can be avoided.

In an embodiment, the length of the balancing line of the power combiner can serve to bridge the distances, in particular wide distances, between the inputs of the power combiner.

Wide distances refer to distances of ≥λ/16.

This allows for a power combiner to be provided that operates efficiently and true to function despite the long distances between individual components.

The possibility to choose from different discrete balancing line lengths allows for a freely selectable distance between the individual components of the power combiner. This means that possible implementations of the power combiner can be designed and used very flexibly.

Furthermore, the balancing circuit of the power combiner can have an additional capacitance. This capacitance can be connected in series or in parallel to the energy absorbers, in particular designed as resistors, of the balancing circuit. This allows the decoupling bandwidth to be increased.

Furthermore, the balancing line with a length of n*λ/2 can be designed at least partially as a coaxial cable or microstrip line. In particular, the part that is designed as a coaxial cable or microstrip line can, in this context, be longer than the remaining parts of the balancing line. This avoids interference that could be transmitted from the balancing line to other assemblies, such as the RF power amplifier stages, or conversely avoids interference that could be transmitted from other assemblies, such as the RF power amplifier stages, to the balancing line.

Furthermore, the power combiner can have a capacitance connecting the output to a ground connection. This capacitance can be used together with the coupling elements, in particular designed as inductors, as a low-pass filter using which unwanted harmonics can be filtered.

Further capacitors can also be used, which are connected to a ground connection before the inductors. This can be used to create a so-called pi circuit consisting of two capacitors and an inductor, which in turn can serve as a low-pass filter.

The power combiner can be arranged on a cooling unit. The cooling unit can be a fluid-cooled cooling unit. This cooling unit can have at least one channel through which a fluid can flow. In this regard, the cooling unit can be made of copper, for example.

The cooling unit can be designed at least partially as a cooling plate. The cooling unit can be made up of multiple parts of different materials. Examples of such a cooling unit are disclosed and described in detail in the following disclosure documents: WO 2019/072894 A1, WO 2013/068004 A1, WO 2014/207185 A1. This means that the power combiner can be used for the high power outputs described in this disclosure, since process heat generated by the components, such as the energy absorbers, in particular designed as resistors, of the balancing circuit, can be discharged directly via the fluid located in the cooling unit. However, the power combiner can in particular be distributed on multiple cooling units, preferably on multiple cooling units which are spaced apart from one another as described above.

Furthermore, the coupling elements, in particular designed as inductors, and the energy absorber(s), in particular designed as resistors, as well as possible capacitances of the power combiner can be arranged on a printed circuit board. The printed circuit board can, for example, be a printed circuit board made of the material FR-4. Such an arrangement of components on a printed circuit board can be easily manufactured and can enable uncomplicated contacting of the components.

In particular, the printed circuit board material can be a polytetrafluoroethylene-based material, also referred to as PTFE material. This material is particularly suitable due to the low dielectric constant and low losses thereof.

The designation FR-4 stands for a class of flame-retardant and flame-resistant composite materials consisting of epoxy resin and glass fiber fabric. The abbreviation FR stands for “flame retardant”.

Polytetrafluoroethylene-based material, also abbreviated as PTFE material, is many times more expensive than FR-4, but it can be used for circuit boards in the RF range because it has particularly low losses in this frequency range. The circuit boards can be designed to be thinner because this material has a lower dielectric constant and also a higher dielectric strength against high electric fields.

In an embodiment, the coupling elements are designed as RF line sections with a fixed characteristic impedance and a length of n*λ/4, where n∈ [symbol] . Especially at higher frequencies, such as ≥40 MHz, such RF line sections can be used advantageously and with low loss as an alternative or in addition to inductors.

In an embodiment, the power combiner can have:
a first power combiner part,
a second power combiner part,
wherein the two power combiner parts are connected to a previously described balancing line with a fixed characteristic impedance and a length of n*λ/2, where n∈ [symbol] . Thus, for the most part, the power combiner can be implemented on a printed circuit board as described in the present disclosure. The balancing line can be routed from one power combiner part to the other.

In particular, the heat-generating part of the power combiner, i.e., the part through which the aforementioned high power flows, can be cooled by the cooling unit described in this disclosure. The balancing line, which generally does not generate as much heat, can be routed freely.

One of these, in particular multiple, preferably all power combiner parts can have the following in a further embodiment:
multiple coupling elements, in particular designed as inductors for connecting one input each to the main output and/or
an energy absorber, in particular multiple energy absorbers, in particular designed as resistors. In this way as well, the power combiner can be implemented for the most part on a printed circuit board as described above. The balancing line can be routed from one power combiner part to the other.

In this way as well, the heat-generating part of the power combiner, i.e., the part through which the aforementioned high power flows, in particular the coupling elements, can be cooled by the cooling unit described in this disclosure.

By connecting RF power amplifier stages to the inputs of the power combiner provided for this purpose, the power combiner can be supplemented to form an RF power amplifier unit. This RF power amplifier unit then represents a functional unit for coupling multiple RF power sources and can supply other consumers or processes with its output power. The connected RF power amplifier stages can be RF transistor amplifiers, for example.

In an embodiment, the RF power amplifier unit can additionally have two heat sink sections, wherein
a first RF power amplifier stage, in particular a first group of RF power amplifier stages, is/are arranged on a first heat sink section, and
a second RF power amplifier stage, in particular a second group of RF power amplifier stages, is/are arranged on a second heat sink section, and
the two heat sink sections are arranged at a distance from one another, and the balancing circuit connects the outputs of the RF power amplifier stages and the balancing line connects the RF power amplifier stages of the first heat sink section to those of the second heat sink section.

In an embodiment, the RF power amplifier unit can additionally have two cooling units, wherein
a first RF power amplifier stage, in particular a first group of RF power amplifier stages, is/are arranged on a first cooling unit, and
a second RF power amplifier stage, in particular a second group of RF power amplifier stages, is/are arranged on a second cooling unit, and
the two cooling units are arranged at a distance from one another, and the balancing circuit connects the outputs of the RF power amplifier stages and the balancing line connects the RF power amplifier stages of the first cooling unit to those of the second cooling unit.

In this way, the high powers for plasma processes described in this disclosure can be generated particularly well. The RF power amplifier stages can be distributed over multiple cooling units or heat sink sections. This allows the heat to be discharged very well. In addition, the RF power amplifier stages interfere less with one another due to the spacing.

One or both cooling units and/or heat sink sections can be arranged between two RF power amplifier stages. Thus, the cooling units and/or heat sink sections can provide shielding for these two RF power amplifier stages, further improving signal quality and reliability.

The spacing can be at least 10 mm, in particular at least 20 mm, measured at the shortest distance between the two cooling units and/or heat sink sections.

As described above, the power combiner can be divided into multiple power combiner parts. Each power combiner part can be arranged on the cooling unit or heat sink section, which group of RF power amplifier stages it is assigned to, i.e., the power outputs of which it is designed to combine. This also allows the power combiner parts to be cooled effectively.

The term “heat sink section” refers to a part of a cooling unit. The cooling unit can be designed at least partially as a cooling plate. The cooling unit can be made up of multiple parts of different materials. Examples of such a cooling unit are disclosed and described in detail in the following disclosure documents: WO 2019/072894 A1, WO 2013/068004 A1, WO 2014/207185 A1.

Advantages of the present disclosure are also achieved by a plasma process supply system having at least one RF power amplifier unit as described above and an impedance matching circuit connected downstream thereof. This allows a previously described power combiner to be used in a particularly advantageous manner, ensuring a high degree of reliability and stability of the system.

Advantages of the present disclosure are also achieved by a plasma process system having a plasma process supply system as described above and a plasma process arrangement connected to the impedance matching circuit.

This allows a previously described power combiner to be used in a particularly advantageous manner, ensuring a high degree of reliability and stability of the system.

Advantages of the present disclosure are also achieved by a method for supplying a load, in particular a plasma process arrangement, with a previously described power amplifier unit and in particular with an impedance matching circuit connected downstream thereof, which, in turn, is particularly preferably connected to a plasma process arrangement, wherein
RF power signals from RF power amplifier stages are supplied to the inputs of the power combiner,
these RF power signals are combined by the power combiner at its output,
and balancing currents flow via a balancing line between the inputs, which has a length of n*λ/2, where n∈ [symbol] , and a fixed characteristic impedance.

In this way, the aforementioned advantages can be achieved in a particularly advantageous way.

Preferred exemplary embodiments of the present disclosure are shown schematically in the drawings and are explained in more detail below with reference to the figures of the drawing.

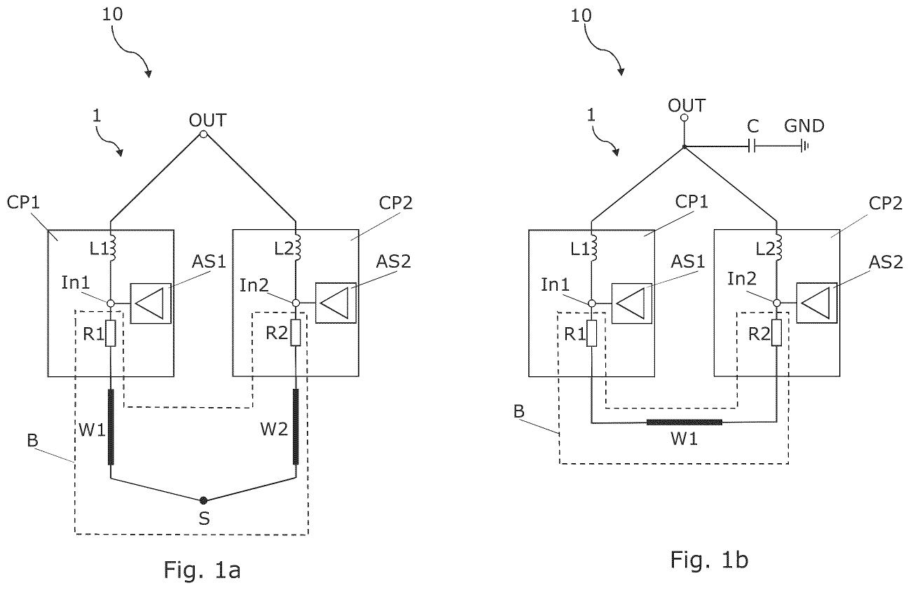

FIG. 1a and b show two embodiments of power amplifier units 10 according to the present disclosure. The power amplifier units 10 each have a power combiner 1, two RF power amplifier stages AS1, AS2 and two cooling units CP1, CP2. The power combiners 1 comprise two inputs In1, In2, a main output OUT, two coupling elements designed as inductors L1, L2 and a balancing circuit B. The RF power amplifier stages AS1, AS2 are connected to the inputs In1, In2, wherein the first RF power amplifier stage AS1 is connected to the first input In1 and the second RF power amplifier stage AS2 is connected to the second input In2. The inductors L1, L2 connect the inputs In1, In2 to the main output OUT, wherein the first inductor L1 connects the first input In1 and the second inductor L2 connects the second input In2 to the main output OUT. The inductors L1, L2 and RF power amplifier stages AS1, AS2 are arranged on the cooling units CP1, CP2.

The first RF power amplifier stage AS1 and the first inductor L1 are arranged on the first cooling unit CP1. The second RF power amplifier stage AS2 and the second inductor L2 are arranged on the second cooling unit CP2.

The balancing circuit B connects the two inputs In1, In2 of the power combiner 1. In FIG. 1a, the balancing circuit B has two energy absorbers designed as resistors R1, R2 and two balancing lines W1, W2 with a length of n*λ/2. Both inputs In1, In2 of the power combiner 1 are connected to a common star point S via the two resistors R1, R2 and the two balancing lines W1, W2.

In FIG. 1b, the balancing circuit B has two energy absorbers designed as resistors R1, R2 and a balancing line W1 with the length n*λ/2. The two inputs In1, In2 are connected to one another via the two resistors R1, R2 and the balancing line W1.

In FIG. 1a and b, both resistors R1, R2 of the balancing circuit B are each arranged on one of the two cooling units CP1, CP2. The first resistor R1 is arranged on the first cooling unit CP1 and connected to the first input In1 in each case. The second resistor R2 is arranged on the second cooling unit CP2 and connected to the second input In2 in each case.

In contrast to the power combiner 1 in FIG. 1a, the power combiner 1 in FIG. 1b has a capacitance C that connects the main output OUT to a ground connection GND.

If the energy absorber is designed as a resistor, its value can advantageously be equal to the characteristic impedance at the corresponding input.

In particular, the fixed resistance as an energy absorber can be equal to an integer multiple of the characteristic impedance at the corresponding input.

In particular, the resistance as an energy absorber can be equal to an integer divisor of the characteristic impedance at the corresponding input.

The resistance as an energy absorber can in particular be equal to 25 Ω, 50 Ω or 100 Ω.

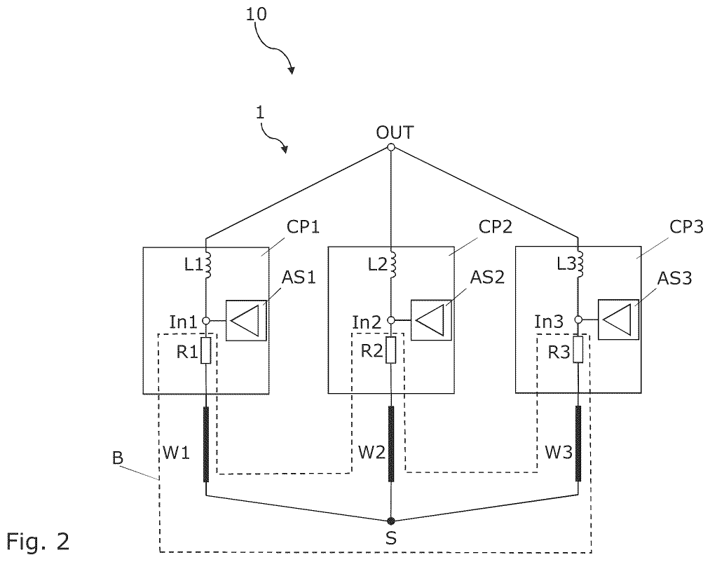

FIG. 2 also shows an embodiment of a power amplifier unit 10 according to the present disclosure. The power amplifier unit 10 is largely identical to the embodiment in FIG. 1a, wherein it has a third RF power amplifier stage AS3 and a third cooling unit CP3. In addition to the components described in FIG. 1a, the power combiner 1 has a third input In3 and a third coupling element designed as an inductor L3. In this embodiment, the balancing circuit B comprises a third balancing line W3 with the length n*λ/2 and a third energy absorber designed as a resistor R3. The third RF power amplifier stage AS3 is connected to the third input In3. The third inductor L3 is used to connect the third input In3 to the main output OUT. The third RF power amplifier stage AS3, the third inductor L3 and the third resistor R3 of the balancing circuit B are arranged on the third cooling unit CP3. The balancing circuit B connects the three inputs In1-In3 via the resistors R1-R3 and the balancing lines W1-W3 with the length n*λ/2 in a common star point S. In this regard, the first resistor R1 and the first balancing line W1 are connected to the first input In1, the second resistor R2 and the second balancing line W2 are connected to the second input In2 and the third resistor R3 and the third balancing line W3 are connected to the third input In3.

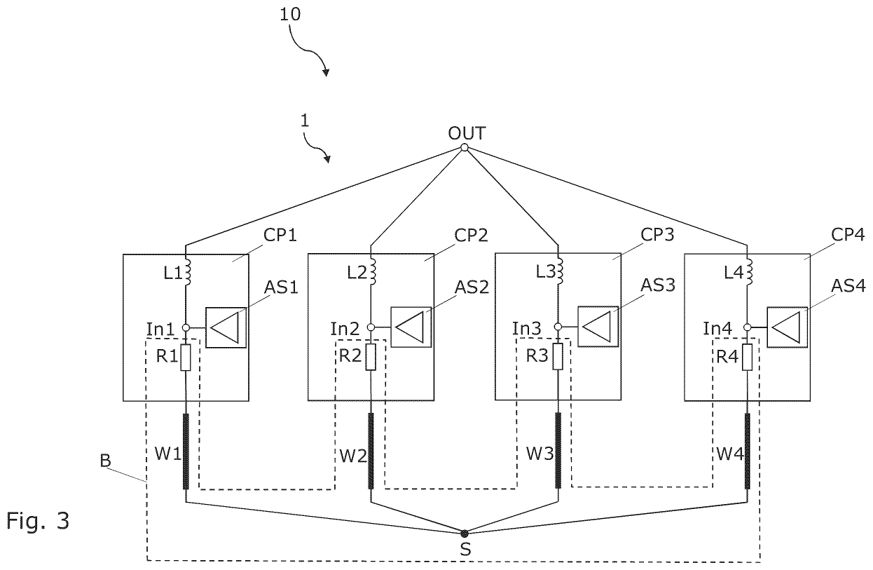

FIG. 3 shows another embodiment of a power amplifier unit 10 according to the present disclosure. This power amplifier unit 10 is largely identical to the embodiment in FIG. 2, wherein it has a fourth RF power amplifier stage AS4 and a fourth cooling unit CP4. In addition to the components described in FIGS. 1a and 2, the power combiner 1 has a fourth input In4 and a fourth coupling element designed as an inductor L4. In this embodiment, the balancing circuit B comprises a fourth balancing line W4 with the length n*λ/2 and a fourth energy absorber designed as a resistor R4. The fourth RF power amplifier stage AS4 is connected to the fourth input In4. The fourth inductor L4 is used to connect the fourth input In4 to the main output OUT. The fourth RF power amplifier stage AS4, the fourth inductor L4 and the fourth resistor R4 of the balancing circuit B are arranged on the fourth cooling unit CP4. The balancing circuit B connects the four inputs In1-In4 via the resistors R1-R4 and the balancing lines W1-W4 with the length n*λ/2 in a common star point S. In this regard, the first resistor R1 and the first balancing line W1 are connected to the first input In1, the second resistor R2 and the second balancing line W2 to the second input In2, the third resistor R3 and the third balancing line W3 to the third input In3 and the fourth resistor R4 and the fourth balancing line W4 to the fourth input In4.

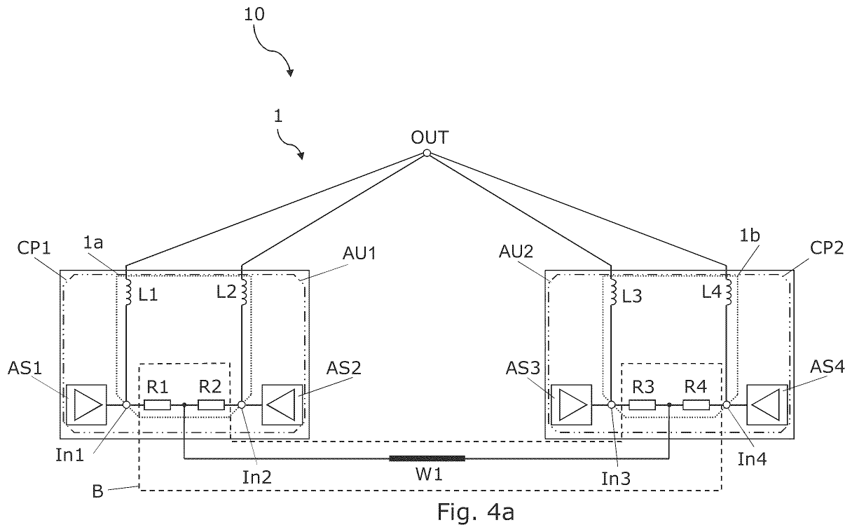

FIG. 4a and b show further embodiments of power amplifier units 10 according to the present disclosure. The power amplifier units 10 each have a power combiner 1, four RF power amplifier stages AS1-AS4 and two cooling units CP1, CP2. The power combiner 1 comprises four inputs In1-In4, a main output OUT, four coupling elements designed as inductors L1-L4 and a balancing circuit B. The RF power amplifier stages AS1-AS4 are connected to the inputs In1-In4. The inductors L1-L4 connect the inputs In1-In4 to the main output OUT.

In FIG. 4a, the four inputs In1-In4 are connected directly to the main output OUT via the four inductors L1-L4.

In FIG. 4b, the first two inputs In1, In2 are connected to one another via the first two inductors L1, L2 in a first output O1 and the second two inputs In3, In4 are connected to one another via the second two inductors L3, L4 in a second output O2. The two outputs O1, O2 are then connected to the main output OUT.

The four inductors L1-L4 and the four RF power amplifier stages AS1-AS4 are arranged on the two cooling units CP1, CP2. The first two inductors L1, L2 and the first two RF power amplifier stages AS1, AS2 are arranged on the first cooling unit CP1. The RF power amplifier stages AS1, AS2 and the components of a first power combiner part 1a, namely the coupling elements designed here as inductors L1, L2 and the energy absorbers designed here as resistors R1, R2, together form a first RF power amplifier stage arrangement AU1. The second two inductors L3, L4 and the second two RF power amplifier stages AS3, AS4 are arranged on the second cooling unit CP2. The RF power amplifier stages AS3, AS4 and the components of a second power combiner part 1b, namely the coupling elements designed here as inductors L3, L4 and the energy absorbers designed here as resistors R3, R4, together form a second RF power amplifier stage arrangement AU2.

The balancing circuit B has four energy absorbers designed as resistors R1-R4 and a balancing line W1 with the length n*λ/2. The four inputs In1-In4 are connected to one another with the balancing circuit B. For this purpose, the first two inputs In1, In2 are connected to one another via the first two resistors R1, R2, arranged on the first cooling unit CP1. In this regard, the first resistor R1 is connected to the first input In1 and the second resistor R2 is connected to the second input In2. Similarly, the second two inputs In3, In4 are connected to one another via the second two resistors R3, R4, arranged on the second cooling unit CP2. In this regard, the third resistor R3 is connected to the third input In3 and the fourth resistor R4 to the fourth input In4. The balancing line W1 then connects all four inputs In1-In4 with one another.

In this way, two, and in particular also more than two, RF power amplifier stage arrangements AU1, AU2 can be connected to one another. If more than two RF power amplifier stage arrangements AU1, AU2 are connected together, multiple balancing lines can be interconnected in a star configuration, as shown analogously in FIGS. 2 and 3 using more than two RF power amplifier stages.

Individual, in particular multiple, especially preferably all, RF power amplifier stage arrangements AU1, AU2 can also have more than two RF power amplifier stages AS1, AS2. Accordingly, these can then also have more than two components of the power combiner parts 1a, 1b, i.e., more than two coupling elements designed here as inductors L1, L2 and more than two energy absorbers designed here as resistors R1, R2.

FIG. 4b also shows a possible connection arrangement of the two outputs O1, O2 of the two RF power amplifier stage arrangements AU1, AU2 with the main output OUT.

In this case, the first output O1 of the first RF power amplifier stage arrangement AU1 is connected to a first transmission line arrangement TL1. The first transmission line arrangement TL1 has a first signal conductor SL1 and a first reference conductor BL1. The second output O2 of the second RF power amplifier stage arrangement AU2 is connected to a second transmission line arrangement TL2. The second transmission line arrangement TL2 has a second signal conductor SL2 and a second reference conductor BL2.

The two signal conductors SL1, SL2 are designed to transmit the respective output signal of the RF power amplifier stage arrangements AU1, AU2. The two reference conductors BL1, BL2 represent the reference potential with respect to the two signal conductors SL1, SL2 and are electrically connected to a potential that cannot be changed with respect to the reference ground. In this case, this potential is the reference ground GND itself.

The two transmission line arrangements TL1, TL2 are brought together and connected to a coupling line arrangement TLC. The coupling line arrangement TLC has a coupling signal line SLC and a coupling reference line BLC. The coupling signal line SLC is designed to transmit the combined output signals of the two RF power amplifier stage arrangements AU1, AU2, i.e., the sum of the output signals of the two RF power amplifier stage arrangements AU1, AU2. The coupling reference conductor BLC represents the reference potential of the coupling signal conductor SLC and is electrically connected to a potential that cannot be changed with respect to the reference ground. In this case, this potential is the reference ground GND itself. The coupling line arrangement TLC is connected to the main output OUT of the power amplifier unit 10.

In the present case, the two transmission line arrangements TL1 and TL2 can be designed as microstrip lines MSL.

In the present case, the coupling line arrangement TLC can also be designed as a microstrip line MSL. Another embodiment for carrying RF power signals, such as a coaxial cable, is also provided.

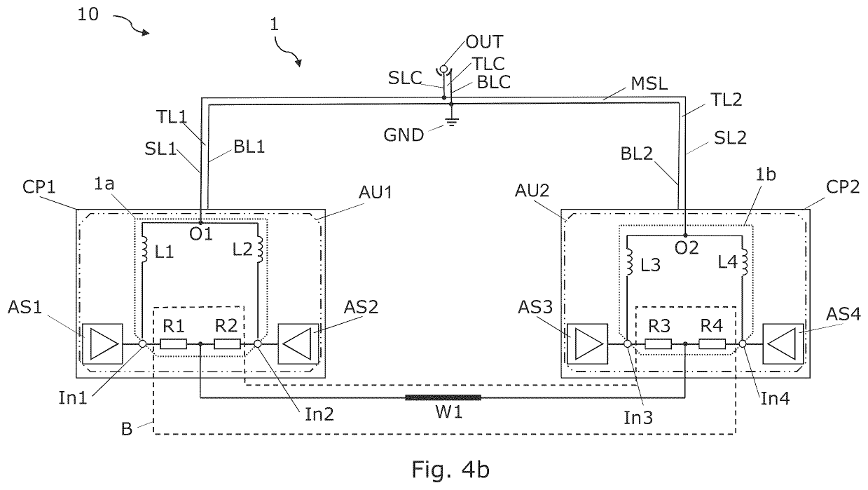

FIG. 5 shows a further embodiment of a power amplifier unit 10 according to the present disclosure. The power amplifier unit 10 is very similar to the power amplifier unit 10 in FIG. 4b only in a different view and the connection arrangement of the two outputs O1, O2 of the two RF power amplifier stage arrangements AU1, AU2 with the main output OUT is designed as a coaxial line CXL. The descriptions pertaining to the two transmission line arrangements TL1, TL2, the two signal conductors SL1, SL2, the two reference conductors BL1, BL2, the coupling line arrangement TLC, the coupling signal line SLC and the coupling reference conductor BLC can be found in the description of FIG. 4b.

The two cooling units CP1, CP2 can each have a heat sink section CS1, CS2. It is also provided that multiple heat sink sections CS1, CS2 are arranged on a common cooling plate, but at a distance from one another locally. For example, the first heat sink section CS1 can be arranged on a first side of a cooling unit and the second heat sink section CS2 can be arranged on the rear side of the same cooling unit.

In contrast to the power amplifier unit 10 in FIG. 4b, the power amplifier unit 10 here has two combiner printed circuit boards PCB1, PCB2.

The first combiner printed circuit board PCB1 is arranged on the first heat sink section CS1 and thus, in this embodiment, also on the first cooling unit CP1. The second combiner printed circuit board PCB2 is arranged on the second heat sink section CS2 and thus, in this embodiment, also on the second cooling unit CP2. Furthermore, the power amplifier unit 10 has the power combiner 1 of FIG. 4b. Of these, the four RF power amplifier stages AS1-AS4 are shown, each divided into the RF power amplifier stage arrangements AU1, AU2. The four coupling elements designed as inductors L1-L4, the main output OUT and the balancing circuit B are also shown. The balancing circuit B comprises the four energy absorbers designed as resistors R1-R4 and the balancing line W1 with the length n*λ/2.

The first two RF power amplifier stages AS1, AS2 are arranged on a first amplifier printed circuit board PCB12. The first two RF power amplifier stages AS1, AS2 are arranged with this first amplifier printed circuit board PCB12 on the first heat sink section CS1 and thus, in this embodiment, also on the first cooling unit CP1. The second two RF power amplifier stages AS3-AS4 are arranged on a second amplifier printed circuit board PCB34. The second two RF power amplifier stages AS3-AS4 are arranged with this second amplifier printed circuit board PCB34 on the second heat sink section CS2 and thus, in this embodiment, also on the second cooling unit CP2.

The first combiner printed circuit board PCB1 can also be combined with the first amplifier printed circuit board PCB12 to form a common printed circuit board.

The second combiner printed circuit board PCB2 can also be combined with the second amplifier printed circuit board PCB34 to form a common printed circuit board.

This simplifies production and reduces the number of cable connections between printed circuit boards, making the overall system more reliable.

The first two inductors L1, L2 and the first two resistors R1, R2 are arranged on the first combiner printed circuit board PCB1. The second two inductors L3, L4 and the second two resistors R3, R4 are arranged on the second combiner printed circuit board PCB2.

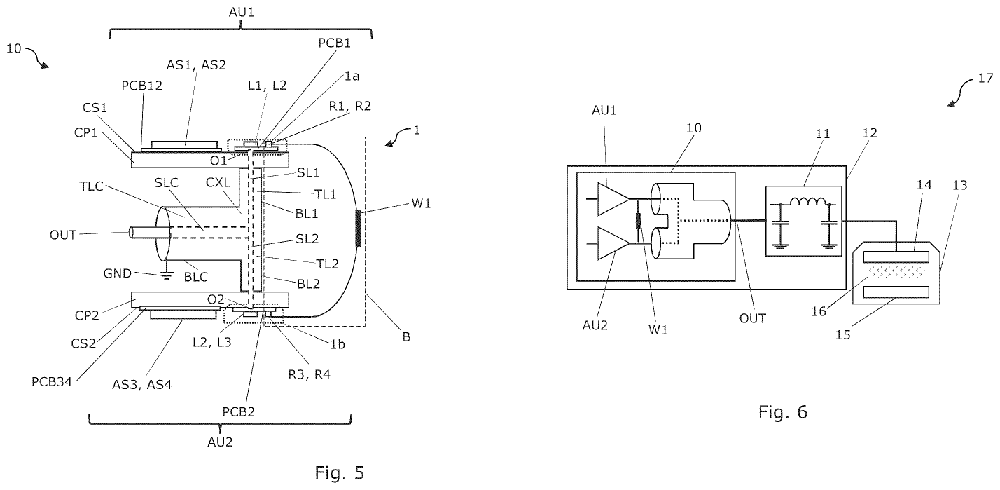

FIG. 6 shows a plasma process system 17 with a plasma process supply system 12.

The plasma process supply system 12 has a power amplifier unit 10 with a power combiner 1. These can be designed as described above.

The plasma process supply system 12 also has an impedance matching circuit 11.

The main output OUT of the power combiner 1 is connected to the input of the impedance matching circuit 11. The output terminal of the impedance matching circuit 11 is connected to the load, in this case a plasma process arrangement in a plasma chamber 13.

The plasma chamber 13 has here:
a substrate 15 that is processed, for example coated or etched, by the plasma 16,
an electrode 14 with which the RF power is coupled into the plasma chamber 13 in order to ignite and maintain the plasma 16.

The impedance matching circuit 11 is designed to transform the input impedance of the plasma process at its output to the output impedance of the power amplifier unit 10. Embodiments of such plasma process systems and/or impedance matching circuits are described, for example, in the following disclosures: DE 10 2009 001 355 A1, DE 10 2011 007 597 A1, DE 10 2011 007 598 A1, WO 2021/209390 A1, WO 2021/255250 A1.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A power combiner for coupling RF signals, in particular designed for a plasma process supply system and a plasma process system, the power combiner being designed for a predefined operating frequency range with a frequency in the range of 2 MHz to 200 MHz, in particular in the range of 10 MHz to 50 MHz, designed for an output power ≥2 kW, preferably ≥4 kW, the power combiner having:
a) multiple inputs designed for connecting RF power amplifier stages,
b) a main output,
c) multiple coupling elements, in particular designed as inductors, wherein each coupling element connects one input to the main output,
d) a balancing circuit which connects the inputs to one another, having:
i) an energy absorber, in particular designed as a resistor, and
ii) a balancing line with a fixed characteristic impedance and a length of n*λ/2, where n∈ [symbol] .

2. The power combiner according to claim 1, wherein the balancing circuit can additionally have a capacitance.

3. The power combiner according to claim 1, wherein the balancing line with a length of n*λ/2 at least partially has a coaxial cable or a microstrip line, and in particular the part which is designed as a coaxial cable or microstrip line is longer than remaining parts of the balancing line.

4. The power combiner according to claim 1, wherein the power combiner has a capacitance connecting the main output to a ground connection.

5. The power combiner according to claim 1, wherein the power combiner is arranged on at least one cooling unit, for example a fluid-cooled cooling plate.

6. The power combiner according to claim 1, wherein the coupling elements, in particular designed as inductors, of the power combiner and the energy absorber, in particular designed as a resistor, of the balancing circuit are arranged on a printed circuit board, in particular on a combiner printed circuit board.

7. The power combiner according to claim 1, comprising:
a first power combiner part,
a second power combiner part,
wherein the first and second power combiner parts are connected to the balancing line with a fixed characteristic impedance and a length of n*λ/2, where n∈ [symbol] .

8. The power combiner according to claim 7, wherein one, in particular multiple, preferably all power combiner parts have:
multiple coupling elements, in particular designed as inductors for connecting one input each to the main output and/or
an energy absorber, in particular multiple energy absorbers, in particular designed as resistors.

9. An RF power amplifier unit having the power combiner according to claim 1, wherein RF power amplifier stages, such as RF transistor amplifiers, are connected to the inputs of the power combiner.

10. The RF power amplifier unit according to claim 9, additionally having two cooling units, wherein
a first RF power amplifier stage, in particular a first group of RF power amplifier stages, are arranged on a first cooling unit,
a second RF power amplifier stage, in particular a second group of RF power amplifier stages, are arranged on a second cooling unit, and
the first and second cooling units are arranged at a distance from one another, and the balancing circuit connects outputs of the RF power amplifier stages and the balancing line connects the RF power amplifier stages of the first cooling unit to those of the second cooling unit.

11. The RF power amplifier unit according to claim 9, additionally having two heat sink sections, wherein
a first RF power amplifier stage, in particular a first group of RF power amplifier stages, are arranged on a first heat sink section,
a second RF power amplifier stage, in particular a second group of RF power amplifier stages, are arranged on a second heat sink section, and
the first and second heat sink sections are arranged at a distance from one another, and the balancing circuit connects outputs of the RF power amplifier stages and the balancing line connects the RF power amplifier stages of the first heat sink section to those of the second heat sink section.

12. A plasma process supply system having at least one RF power amplifier unit according to claim 9, and an impedance matching circuit connected downstream thereof.

13. A plasma process system having a plasma process supply system according to claim 12 and a plasma process arrangement connected to the impedance matching circuit.

14. A method for supplying a load, in particular a plasma process, with a power amplifier unit according to claim 9, and in particular with an impedance matching circuit connected downstream thereof, which, in turn, is particularly preferably connected to a plasma process arrangement, wherein
RF power signals from RF power amplifier stages are supplied to the inputs of the power combiner,
these RF power signals are combined by the power combiner at its main output,
and a balancing current flows via a balancing line between the inputs, wherein the balancing line has a length of n*λ/2, where n∈ [symbol] , and a fixed characteristic impedance.
